(19) United States
(12) Patent Application Publication
(10) Pub. No.: US 2024/0318298 A1
(43) Pub. Date: Sep. 26, 2024

(54) METHOD OF MANUFACTURING MASK ASSEMBLY AND METHOD OF MANUFACTURING DISPLAY DEVICE

(71) Applicant: Samsung Display Co., Ltd., Yongin-si, Gyeonggi-do (KR)

(72) Inventors: Minji Jang, Yongin-si, Gyeonggi-do (KR); Seungjin Lee, Yongin-si, Gyeonggi-do (KR)

(73) Assignee: Samsung Display Co., Ltd., Yongin-si, Gyeonggi-do (KR)

(21) Appl. No.: 18/538,497

(22) Filed: Dec. 13, 2023

(30) Foreign Application Priority Data
Mar. 24, 2023 (KR) 10-2023-0039239
Jun. 16, 2023 (KR) 10-2023-0077452

(51) Int. Cl. C23C 14/04; H10K 71/16

(52) U.S. Cl. CPC C23C 14/042; H10K 71/166

(57) ABSTRACT

A method of manufacturing a mask assembly includes disposing a mask frame including a first opening, disposing a sheet portion on the mask frame, stretching and disposing a mask on the sheet portion, and forming a second opening in the sheet portion by removing a part of the sheet portion that corresponds to the mask.

### CROSS-REFERENCE TO RELATED APPLICATION(S)

This application claims priority to and benefits of Korean Patent Application Nos. 10-2023-0039239 under 35 U.S.C. § 119, filed on Mar. 24, 2023, and 10-2023-0077452 under 35 U.S.C. § 119, filed on Jun. 16, 2023, in the Korean Intellectual Property Office, the entire contents of which are incorporated herein by reference.

### BACKGROUND

### 1. Technical Field

One or more embodiments relate to a method of manufacturing a mask assembly and a method of manufacturing a display device.

### 2. Description of the Related Art

Mobile electronic devices have been widely used. In addition to small electronic devices such as mobile phones, tablet personal computers (PCs) have recently been widely used as mobile electronic devices.

In order to support various functions, such a mobile electronic device may include a display device for providing a user with visual information such as images or video. Recently, as other parts for driving display devices have become smaller, the proportion occupied by display devices in electronic devices has been gradually increasing, and structures capable of being bent from a flat state to have a given angle have also been developed.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

One or more embodiments include a method of manufacturing a mask assembly and a method of manufacturing a display device, in which reliability has improved. However, such a technical problem is an example, and one or more embodiments are not limited thereto.

Additional aspects will be set forth in part in the description which follows and, in part, will be apparent from the description, or may be learned by practice of the embodiments of the disclosure.

According to one or more embodiments, a method of manufacturing a mask assembly may include disposing a mask frame including a first opening; disposing a sheet portion on the mask frame; stretching and disposing a mask on the sheet portion; and forming a second opening in the sheet portion by removing a part of the sheet portion that corresponds to the mask.

The sheet portion may be in the form of a plate and disposed on the mask frame to shield the first opening of the mask frame.

The method may further include stretching the sheet portion and fixing the sheet portion to the mask frame.

The method may further include stretching the mask and fixing the mask to the sheet portion by welding.

The method may further include removing at least a part of a stretched portion of the mask.

The mask may include a plurality of masks spaced apart from each other on the sheet portion, and the method may further include removing parts of stretched portions of the plurality of masks, wherein the parts of the stretched portions may overlap neighboring cell regions of the sheet portion.

A thickness of the sheet portion may be at least 50 μm and not greater than about 200 μm.

The sheet portion may include an iron (Fe)-nickel (Ni) alloy.

The sheet portion may include an iron (Fe)-cobalt (Co)-nickel (Ni) alloy.

A coefficient of thermal expansion of the sheet portion may be less than or equal to about 10⁻⁵/K.

The sheet portion may be magnetic.

According to one or more embodiments, a method of manufacturing a display device may include disposing a mask assembly; and supplying a deposition material toward the mask assembly, wherein the disposing of the mask assembly may include disposing a mask frame including a first opening; disposing a sheet portion on the mask frame; stretching and disposing a mask on the sheet portion; and forming a second opening in the sheet portion by removing a part of the sheet portion that corresponds to the mask.

The sheet portion may be in the form of a plate and disposed on the mask frame to shield the first opening of the mask frame.

The method may further include stretching the mask and fixing the mask to the sheet portion by welding.

The method may further include removing at least a part of a stretched portion of the mask.

A thickness of the sheet portion may be at least about 50 μm and not greater than about 200 μm.

The sheet portion may include an iron (Fe)-nickel (Ni) alloy.

The sheet portion may include an iron (Fe)-cobalt (Co)-nickel (Ni) alloy.

A coefficient of thermal expansion of the sheet portion may be less than or equal to about 10⁻⁵/K.

The sheet portion may be magnetic.

### BRIEF DESCRIPTION OF THE DRAWINGS

The above and other aspects, features, and advantages of embodiments will be more apparent from the following description taken in conjunction with the accompanying drawings, in which:

FIG. 1 is a schematic cross-sectional view of an apparatus for manufacturing a display device, according to an embodiment;

FIG. 2 is a schematic perspective view of a mask frame and a sheet portion, according to an embodiment;

FIGS. 3A to 6B are schematic plan views and schematic cross-sectional views for describing a method of manufacturing a mask assembly, according to an embodiment;

FIG. 7 is a schematic plan view of a display device manufactured by a method of manufacturing a display device, according to an embodiment;

FIG. 8 is a schematic cross-sectional view of a display device manufactured by a method of manufacturing a display device, according to an embodiment; and

FIG. 9 is a schematic diagram of an equivalent circuit of a pixel in a display panel according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are described below, by referring to the figures, to explain aspects of the description.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Throughout the disclosure, the expression “at least one of a, b or c” indicates only a, only b, only c, both a and b, both a and c, both b and c, all of a, b, and c, or variations thereof.

As the description allows for various changes and numerous embodiments, embodiments will be illustrated in the drawings and described in the written description. Effects and features of one or more embodiments and methods of accomplishing the same will become apparent from the following detailed description of the one or more embodiments, taken in conjunction with the accompanying drawings. However, the embodiments may have different forms and should not be construed as being limited to the descriptions set forth herein.

One or more embodiments will be described below in more detail with reference to the accompanying drawings. Those elements that are the same or are in correspondence with each other are rendered the same reference numeral regardless of the figure number, and redundant descriptions thereof may be omitted. In the drawings, sizes, thicknesses, ratios, and dimensions of the elements may be exaggerated for ease of description and for clarity.

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

The singular forms “a,” “an,” and “the” as used herein are intended to include the plural forms as well unless the context clearly indicates otherwise.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

It will be further understood that, when a layer, region, or element is referred to as being on another layer, region, or element, it may be directly or indirectly on the other layer, region, or element. For example, intervening layers, regions, or elements may be present.

Sizes of elements in the drawings may be exaggerated or reduced for convenience of explanation. For example, since sizes and thicknesses of elements in the drawings are arbitrarily illustrated for convenience of explanation, the following embodiments are not limited thereto.

When an embodiment may be implemented differently, a given process order may be performed differently from the described order. For example, two consecutively described processes may be performed substantially at the same time or performed in an order opposite to the described order.

It will be further understood that, when layers, regions, or elements are referred to as being connected to each other, they may be directly connected to each other and/or may be indirectly connected to each other with intervening layers, regions, or elements therebetween. For example, when layers, regions, or elements are referred to as being electrically connected to each other, they may be directly electrically connected to each other and/or may be indirectly electrically connected to each other with intervening layers, regions, or elements therebetween.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

The x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

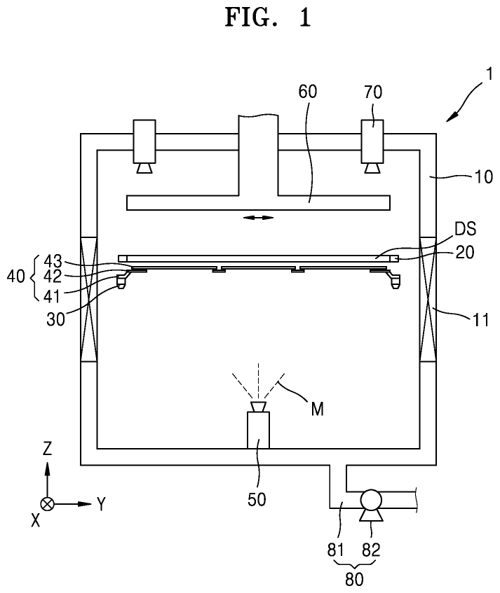

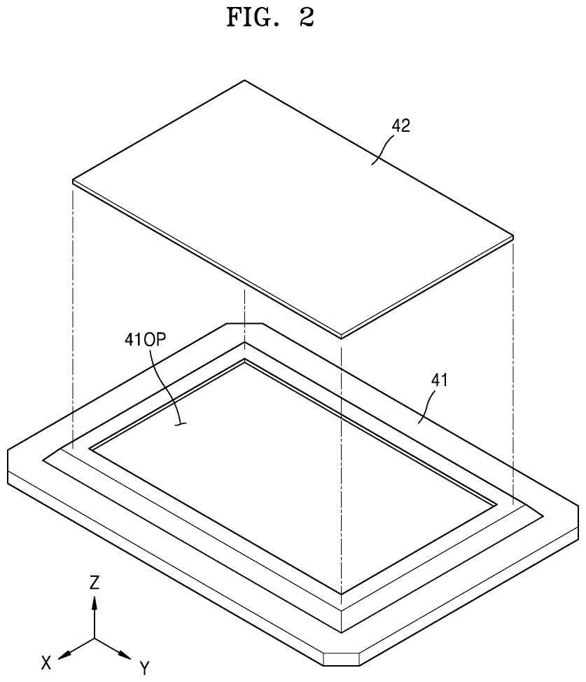

FIG. 1 is a schematic cross-sectional view of an apparatus 1 for manufacturing a display device, according to an embodiment.

The apparatus 1 may include a chamber 10, a first support 20, a second support 30, a mask assembly 40, a deposition source 50, a magnetic force portion 60, a vision portion 70, and a pressure controller 80.

The chamber 10 may include a space therein and may receive a display substrate DS and the mask assembly 40. In this regard, a portion of the chamber 10 may be opened, and a gate valve 11 may be provided in the opened portion of the chamber 10. The opened portion of the chamber 10 may be open or closed according to an operation of the gate valve 11.

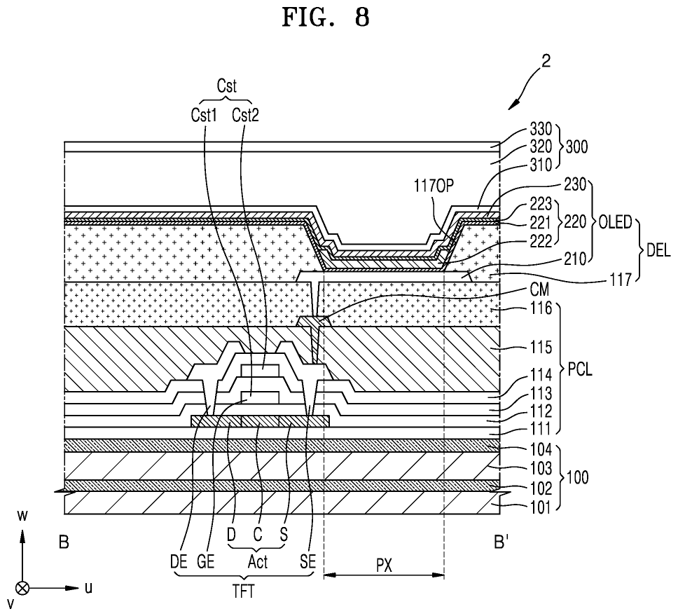

In this regard, the display substrate DS may refer to the display substrate DS in the process of manufacturing a display device, in which at least one of an organic layer, an inorganic layer, and a metal layer is deposited on a substrate 100 (refer to FIG. 8) described below. By way of example, the display substrate DS may be the substrate 100 (refer to FIG. 8) on which none of an organic layer, an inorganic layer, and a metal layer has been deposited yet.

The first support 20 may support the display substrate DS. In this regard, the first support 20 may be in the form of a plate fixed inside of the chamber 10. In an embodiment, the first support 20 may be in the form of a shuttle on which the display substrate DS is seated and which is linearly moveable inside of the chamber 10. In an embodiment, the first support 20 may include an electrostatic chuck or an adhesive chuck arranged (or disposed) in the chamber 10 to be fixed to the chamber 10 or movable inside of the chamber 10.

The second support 30 may support the mask assembly 40. In this regard, the second support 30 may be arranged inside of the chamber 10. The second support 30 may fine-adjust a position of the mask assembly 40. In this regard, the second support 30 may include a separate driver or alignment unit for moving the mask assembly 40 in different directions.

In an embodiment, the second support 30 may be in the form of a shuttle. The second support 30 may have the mask assembly 40 seated thereon and may transport the mask assembly 40. For example, the second support 30 may move out of the chamber 10 to have the mask assembly 40 seated thereon and may enter the chamber 10 from outside of the chamber 10.

In the above case, the first support 20 and the second support 30 may be integral with each other. The first support 20 and the second support 30 may include a movable shuttle. In this regard, the first support 20 and the second support 30 may include a structure in which the mask assembly 40 and the display substrate DS are fixed to each other with the display substrate DS seated on the mask assembly 40, and may linearly move the display substrate DS and the mask assembly 40 simultaneously.

However, hereinafter, a form in which the first support 20 and the second support 30 are separated from each other and arranged at different positions and a form in which the first support 20 and the second support 30 are arranged inside of the chamber 10 will be described in detail for convenience.

The mask assembly 40 may be arranged in the chamber 10 to face the display substrate DS. A deposition material M may pass through the mask assembly 40 and be deposited on the display substrate DS.

The deposition source 50 may face the mask assembly 40, and may supply the deposition material M such that the deposition material M passes through a deposition area of the mask assembly 40 and is deposited on the display substrate DS. In this regard, the deposition source 50 may evaporate or sublimate the deposition material M by applying heat to the deposition material M. The deposition source 50 may be fixed inside of the chamber 10 or may be arranged inside of the chamber 10 to be linearly moveable in one direction or a direction.

The magnetic force portion 60 may be arranged inside of the chamber 10 to face the display substrate DS and/or the mask assembly 40. In this regard, the magnetic force portion 60 may apply magnetic force to the mask assembly 40, thereby pressing the mask assembly 40 toward the display substrate DS.

The vision portion 70 may be arranged in the chamber 10 and may capture images of positions of the display substrate DS and the mask assembly 40. In this regard, the vision portion 70 may include a camera for capturing images of the display substrate DS and the mask assembly 40. Based on the images captured by the vision portion 70, positions of the display substrate DS and the mask assembly 40 may be identified, and the mask assembly 40 may be checked for deformation. Based on the images, a position of the display substrate DS may be fine-adjusted by the first support 20, or a position of the mask assembly 40 may be fine-adjusted by the second support 30. However, hereinafter, a case where a position of the mask assembly 40 is fine-adjusted by the second support 30 to align positions of the display substrate DS and the mask assembly 40 with each other will be described in detail.

The pressure controller 80 may be connected to the chamber 10 to control the internal pressure of the chamber 10. For example, the pressure controller 80 may adjust the internal pressure of the chamber 10 to a level that is the same as or similar to that of atmospheric pressure. The pressure controller 80 may adjust the internal pressure of the chamber 10 to a level that is the same as or similar to that of a vacuum state.

The pressure controller 80 may include a connection pipe 81 connected to the chamber 10 and a pump 82 provided on the connection pipe 81. In this regard, external air may flow in through the connection pipe 81 or gas inside of the chamber 10 may be guided to the outside through the connection pipe 81 according to an operation of the pump 82.

According to a method of manufacturing a display device (not shown) by using the apparatus 1 described above, the display substrate DS may be prepared first.

The pressure controller 80 may maintain the internal pressure of the chamber 10 at a level that is the same as or similar to that of atmospheric pressure, and the gate valve 11 may operate to open the opened portion of the chamber 10.

After that, the display substrate DS may be inserted into the chamber 10 from outside of the chamber 10. In this regard, the display substrate DS may be inserted into the chamber 10 in various ways. For example, the display substrate DS may be inserted into the chamber 10 from outside of the chamber 10 through a robot arm, etc., arranged outside of the chamber 10. In an embodiment, in case that the first support 20 is in the form of a shuttle, the first support 20 may be carried out of the chamber 10 from inside of the chamber 10, and, the display substrate DS may be seated on the first support 20 through a separate robot arm, etc., arranged outside of the chamber 10, and the first support 20 may be inserted into the chamber 10 from outside of the chamber 10.

As described above, the mask assembly 40 may be arranged inside of the chamber 10. In an embodiment, in the same or similar manner as the display substrate DS, the mask assembly 40 may be inserted into the chamber 10 from outside of the chamber 10.

In case that the display substrate DS is inserted into the chamber 10, the display substrate DS may be seated on the first support 20. In this regard, the vision portion 70 may capture images of positions of the display substrate DS and the mask assembly 40. Positions of the display substrate DS and the mask assembly 40 may be identified based on the images captured by the vision portion 70. In this regard, the apparatus 1 may include a separate controller (not shown) to identify positions of the display substrate DS and the mask assembly 40.

In case that positions of the display substrate DS and the mask assembly 40 have been identified, the second support 30 may fine-adjust the position of the mask assembly 40.

After that, the deposition source 50 may operate to supply the deposition material M toward the mask assembly 40, and the deposition material M having passed through the mask assembly 40 may be deposited on the display substrate DS. In this regard, the deposition source 50 may move parallel to the display substrate DS and the mask assembly 40, or the display substrate DS and the mask assembly 40 may move parallel to the deposition source 50. For example, the deposition source 50 may move relative to the display substrate DS and the mask assembly 40. In this regard, the pump 82 may suck in gas inside of the chamber 10 and discharge the gas to the outside, thereby maintaining the internal pressure of the chamber 10 at a level that is the same as or similar to that of a vacuum state.

As described above, the deposition material M supplied from the deposition source 50 may pass through the mask assembly 40 and be deposited on the display substrate DS, and accordingly, layers which may be stacked on a display device described below, for example, at least one of an organic layer, an inorganic layer, and a metal layer, may be formed.

FIG. 2 is a schematic perspective view of a mask frame 41 and a sheet portion 42, according to an embodiment.

The mask frame 41 may have sides connected to each other and may include a first opening 41OP defined by the sides. For example, the first opening 41OP may be surrounded by the sides and may pass through the center of the mask frame 41.

In an embodiment, the mask frame 41 may be a quadrangular frame. However, a shape of the mask frame 41 is not limited thereto, and the mask frame 41 may have various polygonal shapes. Hereinafter, a case in which the mask frame 41 is a quadrangular frame will be described for convenience.

In case that the mask frame 41 is a quadrangular frame, the sides may include a first side extending in a first direction (for example, a direction x or a direction −x) and a second side extending in a second direction (for example, a direction y or a direction −y) intersecting the first direction (for example, the direction x or the direction −x). The first side may include a pair of first sides facing each other, and the second side may include a pair of second sides facing each other, and the pair of first sides and the pair of second sides may be connected to each other. In an embodiment, the first side may be a short side, and the second side may be a long side. However, one or more embodiments are not limited thereto. The first side may be a long side, and the second side may be a short side. By way of example, lengths of the first side and the second side may be the same as each other.

In an embodiment, the sheet portion 42 may be disposed on the mask frame 41. The sheet portion 42 may overlap the first opening 41OP of the mask frame 41. By way of example, the sheet portion 42 may be stretched and may be fixed to the mask frame 41 to overlap the first opening 41OP of the mask frame 41.

The sheet portion 42 may be disposed on the mask frame 41 to shield the first opening 41OP of the mask frame 41 in the form of a plate. The sheet portion 42 may be in the form of a plate and may include no opening.

In an embodiment, the mask frame 41 and the sheet portion 42 may have a rectangular shape. However, one or more embodiments are not limited thereto. The mask frame 41 and the sheet portion 42 may have various polygonal shapes.

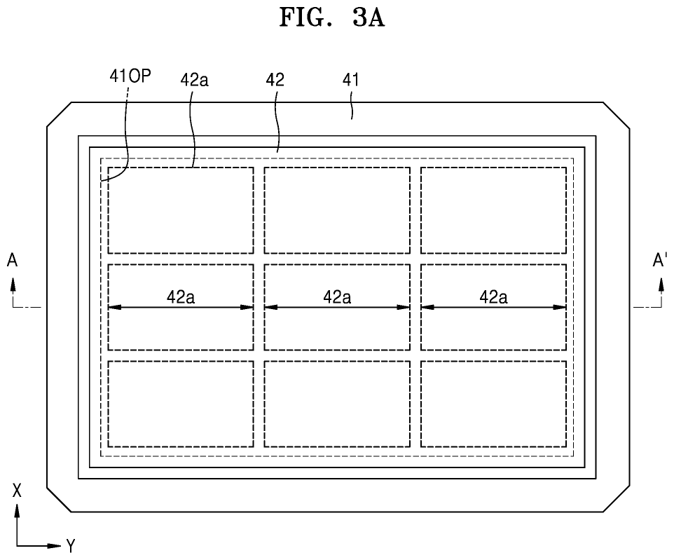

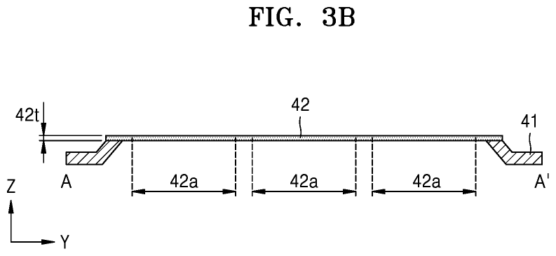

FIGS. 3A to 6B are schematic plan views and schematic cross-sectional views for describing a method of manufacturing the mask assembly 40, according to an embodiment. By way of example, FIGS. 3A, 4A, 5A, and 6A are schematic plan views for describing a method of manufacturing the mask assembly 40, and FIGS. 3B, 4B, 5B, and 6B are schematic cross-sectional views of the method of manufacturing the mask assembly 40, taken along line A-A′ of FIGS. 3A, 4A, 5A, and 6A.

Referring to FIGS. 3A to 6B, a method of manufacturing the mask assembly 40, according to an embodiment, may include an operation of arranging the mask frame 41 including the first opening 41OP, an operation of arranging the sheet portion 42 on the mask frame 41, an operation of stretching and arranging a mask 43 on the sheet portion 42, and an operation of forming a second opening 42OP in the sheet portion 42 by removing a part of the sheet portion 42 that corresponds to the mask 43. This will be described below in more detail.

Referring to FIGS. 3A and 3B, the sheet portion 42 may be disposed on the mask frame 41 including the first opening 41OP. The sheet portion 42 may be stretched and fixed on the mask frame 41. The sheet portion 42 may be disposed on the mask frame 41 to shield the first opening 41OP of the mask frame 41. In other words, the sheet portion 42 may be disposed on the mask frame 41 to overlap the first opening 41OP of the mask frame 41.

The sheet portion 42 may be in the form of a plate. In other words, the sheet portion 42 may include no opening. The sheet portion 42 may have a rectangular shape including no opening. However, one or more embodiments are not limited thereto. The sheet portion 42 may have a polygonal shape including no opening.

A thickness 42t of the sheet portion 42 may be at least about 50 μm and not greater than about 200 μm. In case that a thickness 42t of the sheet portion 42 is less than about 50 μm, stiffness of the sheet portion 42 may be weakened, and thus, the sheet portion 42 may be readily bent during the process. In case that a thickness 42t of the sheet portion 42 is greater than about 200 μm, the deposition material M (refer to FIG. 1) may not be uniformly deposited on the display substrate DS (refer to FIG. 1).

A coefficient of thermal expansion of the sheet portion 42 may be less than or equal to 10⁻⁵/K. In case that a coefficient of thermal expansion of the sheet portion 42 is greater than 10⁻⁵/K, the sheet portion 42 may be deformed during the process, and thus, in case that the deposition material M passes through the mask 43 on the sheet portion 42 and is deposited on the display substrate DS, the accuracy of a position where the deposition material M is deposited on the display substrate DS (pixel position accuracy (PPA)) may decrease.

As described above, the apparatus 1 may include the magnetic force portion 60 (refer to FIG. 1). The magnetic force portion 60 may apply magnetic force to the mask assembly 40 (refer to FIG. 1), thereby pressing the mask assembly 40 toward the display substrate DS. The sheet portion 42 included in the mask assembly 40 may be magnetic. In case that the sheet portion 42 is magnetic, the mask assembly 40 including the sheet portion 42 may also be magnetic, and adhesion between the mask assembly 40 and the display substrate DS may improve, thereby decreasing a distance between the mask assembly 40 and the display substrate DS. In case that a distance between the mask assembly 40 and the display substrate DS is reduced, the accuracy of a position where the deposition material M is deposited on the display substrate DS (pixel position accuracy (PPA)) may be improved during a process in which the deposition material M passes through the mask assembly 40 and is deposited on the display substrate DS.

In an embodiment, a coefficient of thermal expansion of the sheet portion 42 included in the mask assembly 40 may be less than or equal to 10⁻⁵/K. By way of example, the sheet portion 42 included in the mask assembly 40 may be magnetic. Because the mask 43 is disposed on the sheet portion 42, it may be required to facilitate adhesion (or assembly) between the mask 43 and the sheet portion 42. To satisfy the above-described conditions, the sheet portion 42 may include an iron (Fe)-nickel (Ni) alloy or an iron (Fe)-cobalt (Co)-nickel (Ni) alloy.

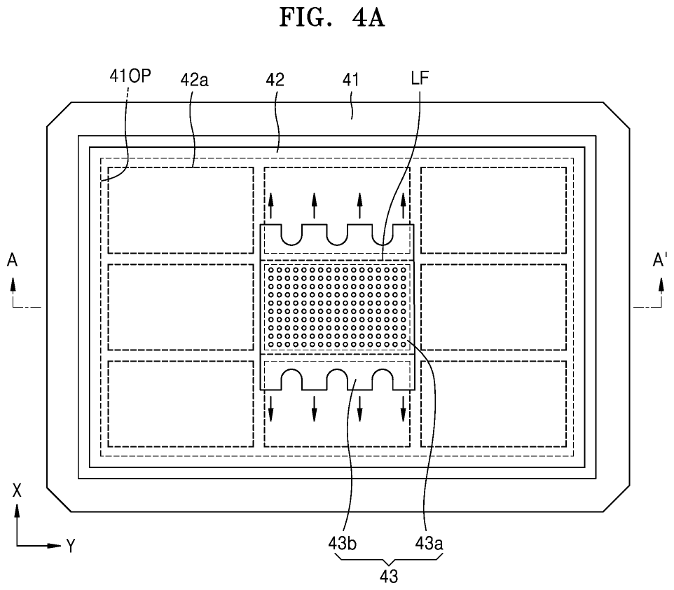

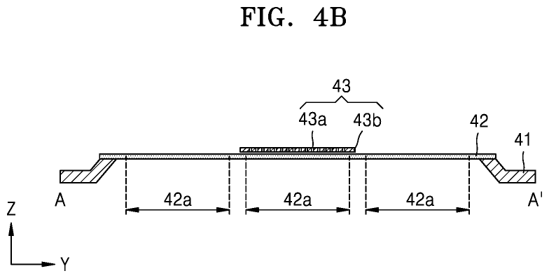

The sheet portion 42 may include cell regions 42a. The cell regions 42a may be arranged in the sheet portion 42 to be apart from each other. The cell regions 42a may each have a rectangular shape. The cell regions 42a may be regions that are removed later to allow the deposition material M to pass through so that the deposition material M supplied from the deposition source 50 (refer to FIG. 1) may be deposited on the display substrate DS. The mask 43 to be disposed on the sheet portion 42 may include a perforated portion 43a (refer to FIG. 4A) including fine holes and a non-perforated portion 43b (refer to FIG. 4A) including no fine holes. The cell region 42a of the sheet portion 42 may be a region overlapping the perforated portion 43a of the mask 43. In other words, the perforated portion 43a of the mask 43 may be disposed over the cell region 42a of the sheet portion 42.

Referring to FIGS. 4A and 4B, the mask 43 may be stretched and arranged on the sheet portion 42. By way of example, the mask 43 may be stretched and arranged thereon to overlap the cell region 42a of the sheet portion 42. The mask 43 may include the perforated portion 43a and the non-perforated portion 43b. The perforated portion 43a of the mask 43 may be a region including fine holes, and the non-perforated portion 43b of the mask 43 may be a region including no fine holes. The deposition material M (refer to FIG. 1) supplied from the deposition source 50 (refer to FIG. 1) may pass through fine holes in the perforated portion 43a of the mask 43 and be deposited on the display substrate DS. On the other hand, the deposition material M supplied from the deposition source 50 may fail to pass through the non-perforated portion 43b of the mask 43, and thus, the deposition material M may not be deposited on a portion of the display substrate DS that overlaps the non-perforated portion 43b of the mask 43.

The perforated portion 43a of the mask 43 may overlap the cell region 42a of the sheet portion 42. The non-perforated portion 43b of the mask 43 may overlap a space between the cell regions 42a of the sheet portion 42. In other words, the non-perforated portion 43b of the mask 43 may be disposed along the edge of the cell region 42a of the sheet portion 42.

By way of example, the mask 43 may be stretched and fixed to the sheet portion 42 by welding. The mask 43 may be fixed to the sheet portion 42 along a fixing line LF while being stretched in a first direction (for example, a direction x or a direction −x). For example, the mask 43 may be welded to the sheet portion 42 along the fixing line LF. Although not shown, the fixing line LF may have a second direction (for example, a direction y or a direction −y) intersecting the first direction (for example, the direction x or the direction −x). The fixing line LF may include fixing lines LF. For example, the fixing line LF may include two fixing lines LF, and the two fixing lines LF may be apart from each other with the cell region 42a of the sheet portion 42 therebetween.

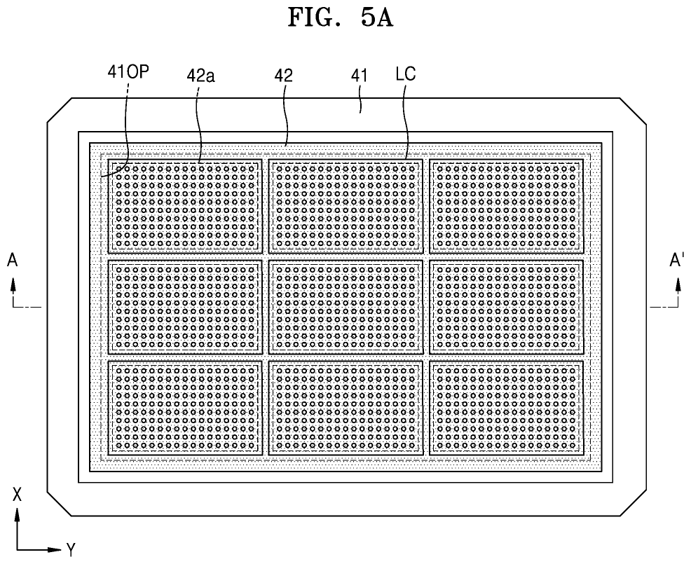

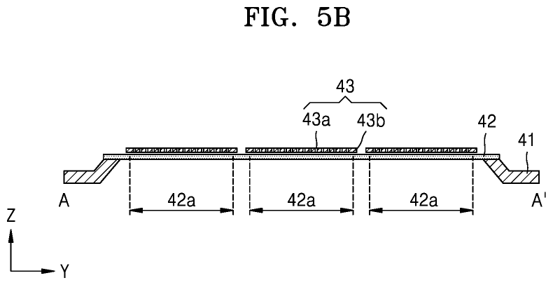

Referring to FIGS. 5A and 5B, at least a part of a portion of the mask 43 that is stretched in the first direction (for example, the direction x or the direction −x) may be removed. A part of the stretched portion of the mask 43 that overlaps a neighboring cell region 42a may be removed. By way of example, while being fixed on the sheet portion 42, the mask 43 may have at least a portion thereof cut along a cutting line LC.

The mask 43 may include the fixing line LF (refer to FIG. 4A) and the cutting line LC. Although not shown, the cutting line LC may be further apart from the cell region 42a of the sheet portion 42 in the first direction (for example, the direction x or the direction −x) that the fixing line LF. In other words, a shortest distance in the first direction (for example, the direction x or the direction −x) between the cell region 42a of the sheet portion 42 and the cutting line LC may be greater than a shortest distance in the first direction (for example, the direction x or the direction −x) between the cell region 42a of the sheet portion 42 and the fixing line LF. The cutting line LC may have the second direction (for example, the direction y or the direction −y) parallel to the fixing line LF. The cutting line LC may include cutting lines LC. For example, the cutting line LC may include two cutting lines LC, and the two cutting lines LC may be apart from each other with the fixing line LF therebetween.

In case that at least a part of the stretched portion of the mask 43 is removed, the perforated portion 43a of the mask 43 may be located or disposed over the cell region 42a of the sheet portion 42, and a part of the non-perforated portion 43b of the mask 43 that has not been removed may be disposed along the edge of the cell region 42a of the sheet portion 42. In other words, at least a part of the non-perforated portion 43b of the mask 43 may be arranged along four sides of a quadrilateral of the perforated portion 43a of the mask 43.

The cell regions 42a may be present in the sheet portion 42, and the mask 43 may be stretched and arranged to overlap one cell region 42a among the cell regions 42a, and after at least a portion of the stretched mask 43 is removed, the mask 43 may be stretched and arranged to overlap another cell region 42a, and at least a portion of the stretched mask 43 may be removed. In other words, an operation of stretching and arranging the mask 43 as much as the number of cell regions 42a and removing at least a portion of the stretched mask 43 may be repeated. In other words, respectively corresponding masks 43 may be disposed over the cell regions 42a of the sheet portion 42.

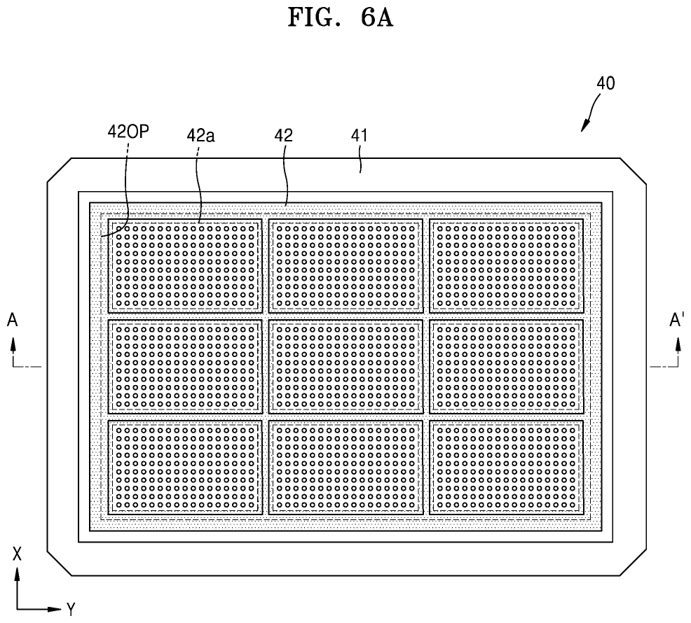

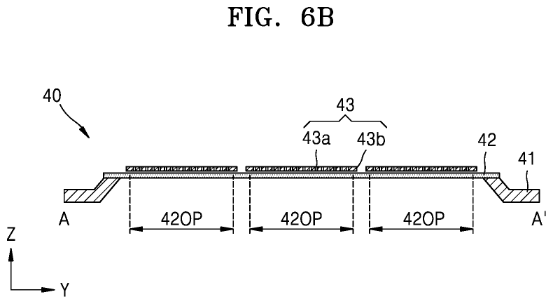

Referring to FIGS. 6A and 6B, the mask assembly 40 may include the mask frame 41, the sheet portion 42, and the mask 43. The sheet portion 42 may include the second opening 42OP. The second opening 42OP may be formed in the sheet portion 42 by removing a part of the sheet portion 42 that corresponds to the mask 43. Second openings 42OP may be formed in the sheet portion 42 by removing the cell regions 42a of the sheet portion 42. Sizes of the cell regions 42a of the sheet portion 42 and sizes of the second openings 42OP of the sheet portion 42 may be the same as each other. The cell regions 42a of the sheet portion 42 overlapping the perforated portion 43a of the mask 43 may be removed, and thus, the deposition material M (refer to FIG. 1) supplied from the deposition source 50 (refer to FIG. 1) may pass through the second opening 42OP of the sheet portion 42 and the perforated portion 43a of the mask 43 and be deposited on the display substrate DS.

According to the related art, a sheet portion in which a second opening had already been formed was arranged on a mask frame, and, a mask was stretched and arranged on the sheet portion. After that, in case that a tensile force was released from the mask, deformation was able to occur in ribs of the sheet portion including the second opening. In other words, in case that a tensile force was released from the mask, deformation was able to occur in ribs of the sheet portion defining the second opening. In case that the ribs of the sheet portion were deformed, the accuracy of a position where a deposition material is deposited on a display substrate (pixel position accuracy (PPA)) decreased in case that the deposition material passed through the second opening in the sheet portion and was deposited on the display substrate.

In an embodiment, the sheet portion 42 not including the second opening 42OP, provided in the form of a plate, and including the cell regions 42a may be arranged on the mask frame 41, the mask 43 may be stretched and fixed to overlap the cell region 42a of the sheet portion 42, and, a portion (or the cell region 42a) of the sheet portion 42 may be removed. Thus, deformation of the sheet portion 42 may be prevented, and the accuracy of a position where the deposition material M passes through the sheet portion 42 and is deposited on the display substrate DS (pixel position accuracy (PPA)) may be improved.

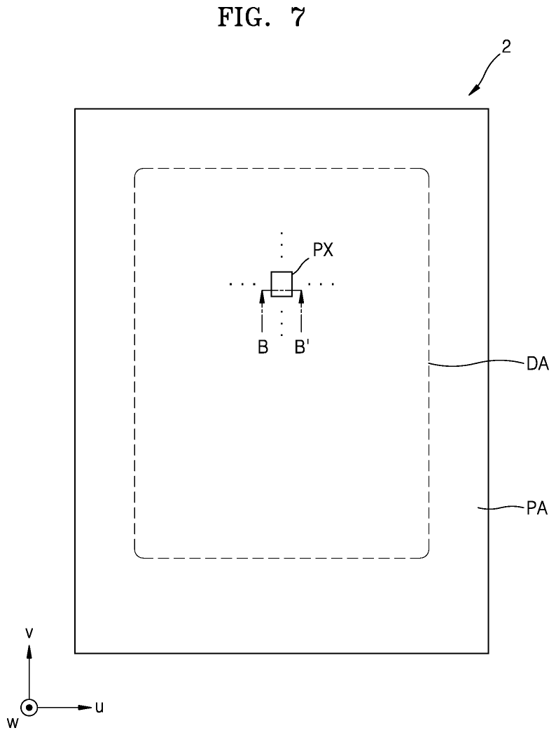

FIG. 7 is a schematic plan view of a display device 2 manufactured by a method of manufacturing a display device, according to an embodiment.

Referring to FIG. 7, the display device 2 manufactured according to an embodiment may include a display area DA and a peripheral area PA located or disposed outside of the display area DA. The display device 2 may provide an image through an array of pixels PX two-dimensionally arranged in the display area DA.

The peripheral area PA is an area where no image is provided, and may entirely or partially surround the display area DA. A driver for providing an electrical signal or power to a pixel circuit corresponding to each of the pixels PX may be arranged in the peripheral area PA. A pad, which is an area to which an electronic device or a printed circuit board may be electrically connected, may be arranged in the peripheral area PA.

Although the display device 2 is described below as including an organic light-emitting diode (OLED) as a light-emitting element, the display device 2 according to one or more embodiments is not limited thereto. In an embodiment, the display device 2 may be a light-emitting display device including an inorganic light-emitting diode, for example, an inorganic light-emitting display. The inorganic light-emitting diode may include a PN junction diode including inorganic semiconductor-based materials. In case that a voltage is applied to the PN junction diode in a forward direction, holes and electrons are injected, and light of a given color may be emitted by converting energy generated by recombination of the holes and electrons into light energy. The inorganic light-emitting diode described above may have a width of several to hundreds of micrometers, and in an embodiments, the inorganic light-emitting diode may be referred to as a micro LED. In an embodiment, the display device 2 may be a quantum dot light-emitting display.

The display device 2 may be used as the display screen of not only portable electronic devices, such as a mobile phone, a smartphone, a tablet personal computer (PC), a mobile communication terminal, an electronic notebook, an e-book, a portable multimedia player (PMP), a navigation system, and an ultra-mobile PC (UMPC), but also various products, such as a television, a notebook computer, a monitor, a billboard, and an Internet of things (IoT) device. The display device 2 according to an embodiment may be used in wearable devices, such as a smartwatch, a watch phone, a glasses-type display, and a head-mounted display (HMD). The display device 2 according to an embodiment may be used as a car's instrument panel, a center information display (CID) placed on a car's center fascia or dashboard, a room mirror display replacing a car's side mirror, or a display screen placed on the back of a front seat as entertainment for a car's rear seat.

FIG. 8 is a schematic cross-sectional view of the display device 2 manufactured by a method of manufacturing a display device, according to an embodiment. By way of example, FIG. 8 is a schematic cross-sectional view of the display device 2, taken along line B-B′ of FIG. 7.

Referring to FIG. 8, the display device 2 may include a stacked structure of the substrate 100, a pixel circuit layer PCL, a display element layer DEL, and an encapsulation layer 300.

The substrate 100 may have a multi-layer structure including a base layer and an inorganic layer, the base layer including polymer resin. For example, the substrate 100 may include a base layer including polymer resin, and a barrier layer of an inorganic insulating layer. For example, the substrate 100 may include a first base layer 101, a first barrier layer 102, a second base layer 103, and a second barrier layer 104 that may be sequentially stacked each other. The first base layer 101 and the second base layer 103 may include polyimide (PI), polyethersulfone (PES), polyarylate, polyetherimide (PEI), polyethylene naphthalate (PEN), polyethylene terephthalate (PET), polyphenylene sulfide (PPS), polycarbonate, cellulose triacetate (TAC) and/or cellulose acetate propionate (CAP). The first barrier layer 102 and the second barrier layer 104 may include an inorganic insulating material, such as silicon oxide, silicon oxynitride and/or silicon nitride. The substrate 100 may be flexible.

The pixel circuit layer PCL may be disposed on the substrate 100. FIG. 8 shows the pixel circuit layer PCL including a thin-film transistor TFT, and a buffer layer 111, a first gate insulating layer 112, a second gate insulating layer 113, an interlayer insulating layer 114, a first planarization insulating layer 115, and a second planarization insulating layer 116 disposed below and/or over elements of the thin-film transistor TFT.

The buffer layer 111 may reduce or prevent penetration of foreign materials, moisture, or external air from below the substrate 100 and may provide a flat surface on the substrate 100. The buffer layer 111 may include an inorganic insulating material, such as silicon oxide, silicon oxynitride and/or silicon nitride, and may have a single-layer or multi-layer structure including the above-described material.

The thin-film transistor TFT on the buffer layer 111 may include a semiconductor layer Act, and the semiconductor layer Act may include polysilicon (poly-Si). By way of example, the semiconductor layer Act may include amorphous silicon (a-Si), an oxide semiconductor, or an organic semiconductor. The semiconductor layer Act may include a channel region C, and a drain region D and a source region S respectively arranged on both sides of the channel region C. A gate electrode GE may overlap the channel region C.

The gate electrode GE may include a low-resistance metal material. The gate electrode GE may include a conductive material including molybdenum (Mo), aluminum (Al), copper (Cu), titanium (Ti), etc., and may have a multi-layer or single-layer structure including the above-described material.

The first gate insulating layer 112 between the semiconductor layer Act and the gate electrode GE may include an inorganic insulating material, such as silicon oxide (SiO₂), silicon nitride (SiNₓ), silicon oxynitride (SiO_{N}), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be zinc oxide (ZnO) and/or zinc peroxide (ZnO₂).

The second gate insulating layer 113 may cover the gate electrode GE. In a similar way to the first gate insulating layer 112, the second gate insulating layer 113 may include an inorganic insulating material, such as silicon oxide (SiO₂), silicon nitride (SiNₓ), silicon oxynitride (SiO_{N}), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be zinc oxide (ZnO) and/or zinc peroxide (ZnO₂).

A top electrode Cst2 of a storage capacitor Cst may be disposed on the second gate insulating layer 113. The top electrode Cst2 may overlap the gate electrode GE therebelow. In this regard, the gate electrode GE and the top electrode Cst2 overlapping each other with the second gate insulating layer 113 therebetween may constitute the storage capacitor Cst. For example, the gate electrode GE may serve as a bottom electrode Cst1 of the storage capacitor Cst.

As described above, the storage capacitor Cst and the thin-film transistor TFT may overlap each other. In an embodiments, the storage capacitor Cst may not overlap the thin-film transistor TFT.

The top electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W) and/or copper (Cu), and may have a single-layer or multi-layer structure including the above-described material.

The interlayer insulating layer 114 may cover the top electrode Cst2. The interlayer insulating layer 114 may include silicon oxide (SiO₂), silicon nitride (SiNₓ), silicon oxynitride (SiO_{N}), aluminum oxide (Al₂O₃), titanium oxide (TiO₂), tantalum oxide (Ta₂O₅), hafnium oxide (HfO₂), or zinc oxide (ZnOₓ). Zinc oxide (ZnOₓ) may be zinc oxide (ZnO) and/or zinc peroxide (ZnO₂). The interlayer insulating layer 114 may have a single-layer or multi-layer structure including the above-described inorganic insulating material.

A drain electrode DE and a source electrode SE may each be on the interlayer insulating layer 114. The drain electrode DE and the source electrode SE may be respectively connected to the drain region D and the source region S through contact holes formed in the insulating layers thereunder. The drain electrode DE and the source electrode SE may include a highly conductive material. The drain electrode DE and the source electrode SE may include a conductive material including molybdenum (Mo), aluminum (Al), copper (Cu), titanium (Ti), etc., and may have a multi-layer or single-layer structure including the above-described material. In an embodiment, the drain electrode DE and the source electrode SE may have a multi-layer structure of titanium (Ti)/aluminum (Al)/titanium (Ti).

The first planarization insulating layer 115 may cover the drain electrode DE and the source electrode SE. The first planarization insulating layer 115 may include an organic insulating material, such as a general commercial polymer, such as polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

The second planarization insulating layer 116 may be disposed on the first planarization insulating layer 115. The second planarization insulating layer 116 may include the same material or similar material as the first planarization insulating layer 115, and may include an organic insulating material, such as a general commercial polymer, such as PMMA or PS, a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

The display element layer DEL may be disposed on the pixel circuit layer PCL having the above-described structure. The display element layer DEL may include an organic light-emitting diode OLED as a display element (for example, a light-emitting element), and the organic light-emitting diode OLED may include a stacked structure of a pixel electrode 210, an intermediate layer 220, and a common electrode 230. The organic light-emitting diode OLED, for example, may emit red, green, or blue light, or may emit red, green, blue, or white light. The organic light-emitting diode OLED may emit light through an emission area, and the emission area may be defined as the pixel PX.

The pixel electrode 210 of the organic light-emitting diode OLED may be electrically connected to the thin-film transistor TFT through contact holes formed in the second planarization insulating layer 116 and the first planarization insulating layer 115 and a contact metal CM disposed on the first planarization insulating layer 115.

The pixel electrode 210 may include conductive oxide, such as indium tin oxide (ITO), indium zinc oxide (IZO), zinc oxide (ZnO), indium oxide (In₂O₃), indium gallium oxide (IGO), or aluminum zinc oxide (AZO). In an embodiment, the pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In an embodiment, the pixel electrode 210 may further include a layer formed of ITO, IZO, ZnO, or In₂O₃ on/under or below the above-described reflective layer.

A bank layer 117 including an opening 117OP exposing a central portion of the pixel electrode 210 may be disposed on the pixel electrode 210. The bank layer 117 may include an organic insulating material and/or an inorganic insulating material. The opening 117OP may define an emission area of light emitted from the organic light-emitting diode OLED. For example, a size/width of the opening 117OP may correspond to a size/width of the emission area. Accordingly, a size and/or width of the pixel PX may depend on a size and/or width of the corresponding opening 117OP of the bank layer 117.

The intermediate layer 220 may include an emission layer 222 corresponding to the pixel electrode 210. The emission layer 222 may include a polymer organic material or low-molecular weight organic material emitting light of a given color. By way of example, the emission layer 222 may include an inorganic light-emitting material or quantum dots.

In an embodiment, the intermediate layer 220 may include a first functional layer 221 and a second functional layer 223 respectively disposed below and over the emission layer 222. The first functional layer 221 may include, for example, a hole transport layer (HTL), or an HTL and a hole injection layer (HIL). The second functional layer 223 is an element disposed on the emission layer 222, and may include an electron transport layer (ETL) and/or an electron injection layer (EIL). Like the common electrode 230 described below, the first functional layer 221 and/or the second functional layer 223 may be common layers entirely covering the substrate 100.

The common electrode 230 may be disposed above the pixel electrode 210 and may overlap the pixel electrode 210. The common electrode 230 may include a conductive material having a low work function. For example, the common electrode 230 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. By way of example, the common electrode 230 may further include a layer, such as ITO, IZO, ZnO, or In₂O₃, on a (semi)transparent layer including the above-described material. The common electrode 230 may be integral to entirely cover the substrate 100.

The encapsulation layer 300 may be disposed on the display element layer DEL and may cover the display element layer DEL. The encapsulation layer 300 may include at least one inorganic encapsulation layer and at least one organic encapsulation layer, and as an embodiment, FIG. 8 shows the encapsulation layer 300 including a first inorganic encapsulation layer 310, an organic encapsulation layer 320, and a second inorganic encapsulation layer 330 that may be sequentially stacked each other.

The first inorganic encapsulation layer 310 and the second inorganic encapsulation layer 330 may include one or more inorganic materials among aluminum oxide, titanium oxide, tantalum oxide, hafnium oxide, zinc oxide, silicon oxide, silicon nitride, and silicon oxynitride. The organic encapsulation layer 320 may include a polymer-based material. Examples of the polymer-based material may include acryl-based resin, epoxy-based resin, polyimide, and polyethylene. In an embodiment, the organic encapsulation layer 320 may include acrylate. The organic encapsulation layer 320 may be formed by curing a monomer or applying a polymer. The organic encapsulation layer 320 may have transparency.

Although not shown, a touch sensor layer may be disposed on the encapsulation layer 300, and an optical functional layer may be disposed on the touch sensor layer. The touch sensor layer may obtain coordinate information according to an external input, for example, a touch event. The optical functional layer may reduce the reflectance of light (external light) incident from the outside toward a display device and/or may improve the color purity of light emitted from the display device. In an embodiment, the optical functional layer may include a phase retarder and/or a polarizer. The phase retarder may be of a film type or a liquid crystal coating type and may include a λ/2 phase retarder and/or a λ/4 phase retarder. The polarizer may also be of a film type or a liquid crystal coating type. The film type may include an elongated synthetic resin film, and the liquid crystal coating type may include liquid crystals arranged in a given arrangement. The phase retarder and the polarizer may further include a protection film.

An adhesive member may be disposed between the touch sensor layer and the optical functional layer. As the adhesive member, a general one may be employed without limitation. The adhesive member may be a pressure-sensitive adhesive (PSA).

The deposition material M described with reference to FIGS. 1 to 6B may include the intermediate layer 220 described with reference to FIG. 8. For example, the deposition material M may include the emission layer 222.

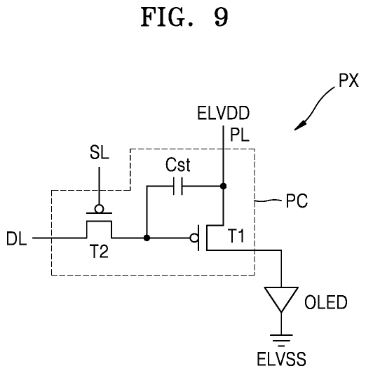

FIG. 9 is a schematic diagram of an equivalent circuit of the pixel PX in a display panel according to an embodiment.

Referring to FIG. 9, each pixel PX may include a pixel circuit PC and a display element connected to the pixel circuit PC, for example, the organic light-emitting diode OLED. The pixel circuit PC may include a first thin-film transistor T1, a second thin-film transistor T2, and the storage capacitor Cst. Each pixel PX may emit, for example, red, green, blue, or white light, through the organic light-emitting diode OLED.

The second thin-film transistor T2, which is a switching thin-film transistor, may be connected to a scan line SL and a data line DL, and may be configured to transfer a data voltage input from the data line DL to the first thin-film transistor T1, based on a switching voltage input from the scan line SL. The storage capacitor Cst may be connected to the second thin-film transistor T2 and a driving voltage line PL and may store a voltage corresponding to a difference between a voltage received from the second thin-film transistor T2 and a first power voltage ELVDD supplied to the driving voltage line PL.

The first thin-film transistor T1, which is a driving thin-film transistor, may be connected to the driving voltage line PL and the storage capacitor Cst, and may be configured to control a driving current flowing through the organic light-emitting diode OLED from the driving voltage line PL, in response to a voltage value stored in the storage capacitor Cst. The organic light-emitting diode OLED may emit light having given brightness according to the driving current. An opposite electrode (for example, a cathode) of the organic light-emitting diode OLED may receive a second power voltage ELVSS.

Although FIG. 9 shows the pixel circuit PC including two thin-film transistors and one storage capacitor, one or more embodiments are not limited thereto. The number of thin-film transistors and the number of storage capacitors may be variously modified according to the design of the pixel circuit PC. For example, the pixel circuit PC may further include four or five or more thin-film transistors in addition to the two thin-film transistors described above. According to the related art, a sheet portion in which a second opening had already been formed was arranged on a mask frame, and, a mask was stretched and arranged on the sheet portion. After that, in case that a tensile force was released from the mask, deformation was able to occur in ribs of the sheet portion including the second opening. In other words, in case that a tensile force was released from the mask, deformation was able to occur in ribs of the sheet portion defining the second opening. In case that the ribs of the sheet portion were deformed, the accuracy of a position where a deposition material is deposited on a display substrate (pixel position accuracy (PPA)) decreased in case that the deposition material passed through the second opening in the sheet portion and was deposited on the display substrate.

In an embodiment, the sheet portion 42 not including the second opening 42OP, provided in the form of a plate, and including the cell regions 42a may be arranged on the mask frame 41, the mask 43 may be stretched and fixed to overlap the cell region 42a of the sheet portion 42, and, a portion (or the cell region 42a) of the sheet portion 42 may be removed. Thus, deformation of the sheet portion 42 may be prevented, and the accuracy of a position where the deposition material M passes through the second opening 42OP in the sheet portion 42 and is deposited on the display substrate DS (pixel position accuracy (PPA)) may be improved.

According to one or more of the above embodiments, a method of manufacturing a mask assembly and a method of manufacturing a display device, in which reliability has improved, may be implemented. However, one or more embodiments are not limited by such an effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope and as defined by the following claims.

What is claimed is:

1. A method of manufacturing a mask assembly, the method comprising:
disposing a mask frame comprising a first opening;
disposing a sheet portion on the mask frame;
stretching and disposing a mask on the sheet portion; and
forming a second opening in the sheet portion by removing a part of the sheet portion that corresponds to the mask.

2. The method of claim 1, wherein the sheet portion is in a form of a plate and disposed on the mask frame to shield the first opening of the mask frame.

3. The method of claim 1, further comprising:
stretching the sheet portion and fixing the sheet portion to the mask frame.

4. The method of claim 1, further comprising:
stretching the mask and fixing the mask to the sheet portion by welding.

5. The method of claim 4, further comprising:
removing at least a part of a stretched portion of the mask.

6. The method of claim 5, wherein
the mask comprises a plurality of masks spaced apart from each other on the sheet portion,
the method further comprises removing parts of stretched portions of the plurality of masks, and
the parts of the stretched portions overlap neighboring cell regions of the sheet portion.

7. The method of claim 1, wherein a thickness of the sheet portion is at least about 50 μm and not greater than about 200 μm.

8. The method of claim 1, wherein the sheet portion comprises an iron (Fe)-nickel (Ni) alloy.

9. The method of claim 1, wherein the sheet portion comprises an iron (Fe)-cobalt (Co)-nickel (Ni) alloy.

10. The method of claim 1, wherein a coefficient of thermal expansion of the sheet portion is less than or equal to about 10⁻⁵/K.

11. The method of claim 1, wherein the sheet portion is magnetic.

12. A method of manufacturing a display device, the method comprising:
disposing a mask assembly; and
supplying a deposition material toward the mask assembly, wherein
the disposing of the mask assembly comprises:
disposing a mask frame comprising a first opening;
disposing a sheet portion on the mask frame;
stretching and disposing a mask on the sheet portion; and
forming a second opening in the sheet portion by removing a part of the sheet portion that corresponds to the mask.

13. The method of claim 12, wherein the sheet portion is in a form of a plate and disposed on the mask frame to shield the first opening of the mask frame.

14. The method of claim 12, further comprising:
stretching the mask and fixing the mask to the sheet portion by welding.

15. The method of claim 14, further comprising:
removing at least a part of a stretched portion of the mask.

16. The method of claim 12, wherein a thickness of the sheet portion is at least about 50 μm and not greater than about 200 μm.

17. The method of claim 12, wherein the sheet portion comprises an iron (Fe)-nickel (Ni) alloy.

18. The method of claim 12, wherein the sheet portion comprises an iron (Fe)-cobalt (Co)-nickel (Ni) alloy.

19. The method of claim 12, wherein a coefficient of thermal expansion of the sheet portion is less than or equal to about 10⁻⁵/K.

20. The method of claim 12, wherein the sheet portion is magnetic.
